(19) United States
(12) Patent Application Publication
(10) Pub. No.: US 2022/0254962 A1
(43) Pub. Date: Aug. 11, 2022

(54) OPTICAL ARRANGEMENTS IN COVER STRUCTURES FOR LIGHT EMITTING DIODE PACKAGES AND RELATED METHODS

(71) Applicant: CreeLED, Inc., Durham, NC (US)

(72) Inventors: Derek Miller, Raleigh, NC (US); Peter Scott Andrews, Durham, NC (US); Colin Blakely, Raleigh, NC (US); Brian T. Collins, Holly Springs, NC (US)

(21) Appl. No.: 17/173,735

(22) Filed: Feb. 11, 2021

(51) Int. Cl. H01L 33/48; H01L 25/075; H01L 33/50; H01L 33/58

(52) U.S. Cl. CPC H01L 33/486; H01L 25/0753; H01L 33/505; H01L 2933/0091; H01L 2933/0041; H01L 2933/0058; H01L 33/58

(57) ABSTRACT

Optical arrangements in cover structures for packaged light-emitting diode (LED) devices are disclosed. LED packages may include a cover structure arranged over one or more LED chips. The cover structure may include arrangements of one or more sublayers or regions configured with different optical arrangements for tailoring emission characteristics for the LED package. The one or more sublayers or regions may include one or more arrangements of optical materials, including lumiphoric materials, materials with different indexes of refraction, light-scattering materials, and light-diffusing materials individually or in various combinations with one another to provide one or more of improved light output, increased light extraction, improved emission uniformity, and improved emission contrast for the LED package. Related methods include providing individual sheets of precursor materials that include different optical arrangements and firing the sheets together to form cover structures.

### FIELD OF THE DISCLOSURE

The present disclosure relates to solid-state lighting devices including light-emitting diodes (LEDs), and more particularly to optical arrangements in cover structures for packaged LED devices and related methods.

### BACKGROUND

Solid-state lighting devices such as light-emitting diodes (LEDs) are increasingly used in both consumer and commercial applications.

Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from silicon carbide, gallium nitride, gallium phosphide, aluminum nitride, gallium arsenide-based materials, and/or from organic semiconductor materials. Photons generated by the active region are initiated in all directions.

Typically, it is desirable to operate LEDs at the highest light emission efficiency possible, which can be measured by the emission intensity in relation to the output power (e.g., in lumens per watt). A practical goal to enhance emission efficiency is to maximize extraction of light emitted by the active region in the direction of the desired transmission of light. Light extraction and external quantum efficiency of an LED can be limited by a number of factors, including internal reflection. According to the well-understood implications of Snell's law, photons reaching an interface between an LED surface and the surrounding environment or even an internal interface of the LED can be either refracted or internally reflected. If photons are internally reflected in a repeated manner, then such photons eventually are absorbed and never provide visible light that exits an LED.

LED packages have been developed that can provide mechanical support, electrical connections, and encapsulation for LED emitters. Light emissions that exit surfaces of LED emitters typically interact with various elements or surfaces of the LED package before exiting, thereby increasing opportunities for light loss and potential non-uniformity of light emissions. As such, there can be challenges in producing high quality light with desired emission characteristics while also providing high light emission efficiency in LED packages.

The art continues to seek improved LEDs and solid-state lighting devices having desirable illumination characteristics capable of overcoming challenges associated with conventional lighting devices.

### SUMMARY

The present disclosure relates to solid-state lighting devices including light-emitting diodes (LEDs), and more particularly to optical arrangements in cover structures for packaged LED devices. An LED package may include one or more LED chips and a cover structure that is arranged over the one or more LED chips that may provide protection from environmental exposure to underlying portions of the LED package. The cover structure may include arrangements of one or more sublayers or regions that may be configured with different optical arrangements for providing improved emission characteristics for the LED package. The one or more sublayers or regions of the cover structure may include one or more various arrangements of optical materials, including lumiphoric materials, materials with different indexes of refraction, light-scattering materials, and light-diffusing materials individually or in various combinations with one another to provide one or more of improved light output, increased light extraction, improved emission uniformity, and improved emission contrast for the LED package. Related methods include providing individual sheets of precursor materials that include different optical arrangements and firing the sheets together to form cover structures.

In one aspect, an LED package comprises: a submount; at least one LED chip on the submount; and a cover structure on the at least on LED chip, wherein the cover structure comprises: a first sublayer comprising a first arrangement of a first optical material; and a second sublayer comprising a second arrangement of a second optical material, wherein the first arrangement is different than the second arrangement. In certain embodiments, the cover structure comprises a host material of at least one of a glass and a ceramic. In certain embodiments, the first optical material and the second optical material comprise one or more of a lumiphoric material, a material with a different index of refraction than the host material, a light-scattering material, and a light-diffusing material. In certain embodiments, the first sublayer is arranged between the at least one LED chip and the second sublayer; and the first optical material and the second optical material comprise a same lumiphoric material, wherein the first arrangement of the first sublayer comprises a higher quantity of the lumiphoric material than the second arrangement of the second sublayer.

The cover structure may further comprise a third sublayer and a fourth sublayer that each comprise the lumiphoric material, and the lumiphoric material is arranged in decreasing quantities in the cover structure in a direction away from the at least one LED chip. In certain embodiments, the first sublayer is arranged between the at least one LED chip and the second sublayer; the first optical material comprises a first lumiphoric material; and the second optical material comprise a second lumiphoric material that is different than the first lumiphoric material. In certain embodiments, the first lumiphoric material is configured to provide a longer peak wavelength than the second lumiphoric material. The LED package may further comprise at least one additional sublayer that is devoid of lumiphoric materials. In certain embodiments, the at least one additional sublayer comprises light-scattering particles.

In certain embodiments, the second optical material is arranged in a first subregion of the second sublayer. In certain embodiments, a lateral width of the first subregion of the second sublayer is less than a lateral width of the cover structure. In certain embodiments, the first subregion of the second sublayer is laterally surrounded by a second subregion of the second sublayer. The second subregion may comprise light-scattering materials and may be devoid of lumiphoric materials. In certain embodiments, the second subregion of the second sublayer comprises the first optical material.

In certain embodiments, the cover structure forms a plurality of openings that are registered with the plurality of streets. In certain embodiments, the cover structure comprises a beveled edge. In certain embodiments, a surface of the cover structure comprises a nonplanar emission surface. In certain embodiments, the LED package comprises a non-light-emitting element on the submount that has a greater height than a height of the at least one LED chip, wherein the cover structure forms a recess that is registered with the non-light-emitting element.

In certain embodiments, the at least one LED chip is a monolithic LED chip that comprises a plurality of individual LED regions of the monolithic LED chip. A plurality of streets may be defined at least partially through the monolithic LED chip that define the plurality of individual LED regions. In certain embodiments, the plurality of streets are at least partially filled with a light-altering material.

In another aspect, an LED package comprises: a submount; at least one LED chip on the submount; and a cover structure on the at least on LED chip, wherein the cover structure comprises: a first sublayer within the cover structure, wherein the first sublayer comprises a first lumiphoric material; and a second sublayer within the cover structure, wherein the second sublayer comprises a second lumiphoric material that is different than the first lumiphoric material. The LED package may further comprise at least one additional sublayer that is devoid of lumiphoric materials. In certain embodiments, the at least one additional sublayer comprises light-scattering particles. In certain embodiments, the second lumiphoric material is arranged in a first subregion of the second sublayer. In certain embodiments, a lateral width of the first subregion of the second sublayer is less than a lateral width of the cover structure. In certain embodiments, the first subregion of the second sublayer is laterally surrounded by a second subregion of the second sublayer. In certain embodiments, the second subregion comprises light-scattering materials and is devoid of lumiphoric materials. In certain embodiments, the second subregion of the second sublayer comprises the first lumiphoric material. The at least one LED chip may comprise a monolithic LED chip that comprises a plurality of individual LED regions of the monolithic LED chip. A plurality of streets may be defined at least partially through the monolithic LED chip that define the plurality of individual LED regions. In certain embodiments, the plurality of streets are at least partially filled with a light-altering material.

In another aspect, a method comprises: providing a first sheet comprising a precursor material and a first arrangement of a first optical material; providing a second sheet comprising the precursor material and a second arrangement of a second optical material that is different than the first arrangement of the first optical material; pressing and firing the first sheet together with the second sheet to form a cover structure that comprises the first arrangement and the second arrangement embedded within the cover structure; and attaching the cover structure over an LED chip. The precursor material may comprise at least one of glass frit and ceramic materials that forms a host material for the cover structure after pressing and firing. In certain embodiments, the first optical material and the second optical material comprise one or more of a lumiphoric material, a material with a different index of refraction than the host material, a light-scattering material, and a light-diffusing material. In certain embodiments, the first optical material and the second optical material comprise a same lumiphoric material, and the first arrangement comprises a higher quantity of the lumiphoric material than the second arrangement. In certain embodiments, the first optical material and the second optical material comprise different lumiphoric materials. The method may further comprise reducing a thickness of the cover structure before attaching the cover structure over the LED chip. In certain embodiments, the first arrangement comprises a subregion of the first sheet that comprises the first optical material. The method may further comprise forming a well in the first sheet and filling the well with the first optical material to form the subregion before pressing and firing the first sheet together with the second sheet. The method may further comprise selectively removing one or more portions of the cover structure. In certain embodiments, the one or more portions of the cover structure are selectively removed after the cover structure is attached over the LED chip.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A illustrates a cross-sectional view at a first fabrication step for forming a cover structure for light-emitting diode (LED) applications where multiple sheets of precursor materials are provided that have different optical arrangements from one another to provide the cover structure with varying optical materials.

FIG. 1B illustrates a cross-sectional view at a second fabrication step where the multiple sheets of FIG. 1A are pressed together and fired to form the cover structure.

FIG. 1C illustrates a cross-sectional view at a third fabrication step where the cover structure is singulated.

FIG. 1D illustrates a cross-sectional view at a fourth fabrication step where the cover structure is provided in a light-receiving arrangement with an LED chip.

FIG. 2A illustrates a cross-sectional view at a first fabrication step for forming a cover structure for LED applications where a first sheet of precursor materials is patterned with features that may be used for forming the cover structure with optical materials that may be varied in vertical and/or horizontal configurations.

FIG. 2B is a perspective view of a second fabrication step where portions of the first sheet within outlines of the features of FIG. 2A are removed to form openings or wells in the sheet.

FIG. 2C is a perspective view of a third fabrication step where the wells are filled with a first optical material having a different optical characteristic than the remaining portions of the sheet.

FIG. 2D is a perspective view of a fourth fabrication step where the first sheet with filled wells is provided over a second sheet before being pressed together.

FIG. 2E is a perspective view of a fifth fabrication step where the first and second sheets are pressed together and fired to form a cover structure.

FIG. 2F illustrates a cross-sectional view at a sixth fabrication step where the cover structure may be singulated.

FIG. 2G illustrates a cross-sectional view at a seventh fabrication step where the cover structure is provided in a light-receiving arrangement with the LED chip.

FIG. 3 is a cross-sectional view of an LED package that includes a cover structure provided over an LED chip where the cover structure includes a progressively decreasing quantity of lumiphoric material in a direction away from the LED chip.

FIG. 4 is a cross-sectional view of an LED package that is similar to the LED package of FIG. 3 where the cover structure includes a progressively increasing quantity of the lumiphoric material in a direction away from the LED chip.

FIG. 5 is a cross-sectional view of an LED package that is similar to the LED package of FIG. 3 but includes different lumiphoric materials in one or more sub-layers of the cover structure.

FIG. 6 is a cross-sectional view of an LED package that is similar to the LED package of FIG. 5 for embodiments where light-scattering particles and/or light-diffusing particles are included in one or more of the sub-layers of the cover structure.

FIG. 7 is a cross-sectional view of an LED package that is similar to the LED package of FIG. 3 and includes at least one sublayer with a subregion of optical material.

FIG. 8 is a cross-sectional view of an LED package that is similar to the LED package of FIG. 7 and where one or more subregions include light-scattering particles and/or light-diffusing particles.

FIG. 9 is a cross-sectional view of an LED package that is similar to the LED package of FIG. 6 and where one sublayer includes multiple subregions and light-scattering and/or light-diffusing particles are provided in less than all of the subregions.

FIG. 10 is a cross-sectional view of an LED package that is similar to the LED package of FIG. 6 and where one or more sublayers include laterally or horizontally varied lumiphoric materials.

FIG. 11 is a cross-sectional view of an LED package that is similar to the LED package of FIG. 3 but where one or more sublayers include different index of refraction characteristics relative to one another.

FIG. 12 is a cross-sectional view of an LED package that is similar to the LED package of FIG. 11 for embodiments where the LED package is devoid of lumiphoric materials and where one or more of the sublayers include different index of refraction characteristics relative to one another.

FIG. 13 is a cross-sectional view of an LED package that is similar to the LED package of FIG. 11 for embodiments where multiple ones of the sublayers include lumiphoric materials that differ from one another and at least one of the sublayers includes a light-scattering and/or light-diffusing material.

FIG. 14 is a cross-sectional view of an LED package that is similar to the LED package of FIG. 11 for embodiments where index of refraction values may also be varied laterally within one or more of the sublayers.

FIG. 15 is a cross-sectional view of an LED package that is similar to the LED package of FIG. 7 where one or more lateral portions of the cover structure have been selectively removed.

FIG. 16 is a cross-sectional view of an LED package that is similar to the LED package of FIG. 15 where one or more portions of the cover structure have been selectively removed to form one or more features in surfaces of the cover structure.

FIG. 17 is a cross-sectional view of an LED package that is similar to the LED package of FIG. 3 for embodiments where the LED chip is a monolithic LED chip with streets that define individual LED portions of the LED chip.

FIG. 18 is a cross-sectional view of an LED package that is similar to the LED package of FIG. 17 for embodiments where the streets may be formed though an entire thickness of the LED chip.

FIG. 19 is a cross-sectional view of an LED package that is similar to the LED package of FIG. 18 for embodiments where recesses and/or openings are formed in the cover structure that are registered with the streets.

FIG. 20 is a cross-sectional view of an LED package that is similar to the LED package of FIG. 3 and where the cover structure is formed with one or more beveled edges.

FIG. 21 is a cross-sectional view of an LED package that is similar to the LED package of FIG. 3 and where the cover structure is formed with a textured surface for light extraction.

FIG. 22 is a cross-sectional view of an LED package that is similar to the LED package of FIG. 3 and where the cover structure is formed with a patterned surface for light extraction.

FIG. 23 is a cross-sectional view of an LED package that is similar to the LED package of FIG. 3 and where the cover structure is formed with a shape that corresponds with a non-light emitting element of the LED package.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to solid-state lighting devices including light-emitting diodes (LEDs), and more particularly to optical arrangements in cover structures for packaged LED devices. An LED package may include one or more LED chips and a cover structure that is arranged over the one or more LED chips that may provide protection from environmental exposure to underlying portions of the LED package. The cover structure may include arrangements of one or more sublayers or regions that may be configured with different optical arrangements for providing improved emission characteristics for the LED package. The one or more sublayers or regions of the cover structure may include one or more various arrangements of optical materials, including lumiphoric materials, materials with different indexes of refraction, light-scattering materials, and light-diffusing materials individually or in various combinations with one another to provide one or more of improved light output, increased light extraction, improved emission uniformity, and improved emission contrast for the LED package. Related methods include providing individual sheets of precursor materials that include different optical arrangements and firing the sheets together to form cover structures.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include silicon carbide (SiC), organic semiconductor materials, and other Group III-V systems such as gallium phosphide (GaP), gallium arsenide (GaAs), and related compounds.

The active LED structure may be grown on a growth substrate that can include many materials, such as sapphire, SiC, aluminum nitride (AlN), and GaN, with a suitable substrate being a 4H polytype of SiC, although other SiC polytypes can also be used including 3C, 6H, and 15R polytypes. SiC has certain advantages, such as a closer crystal lattice match to Group III nitrides than other substrates and results in Group III nitride films of high quality. SiC also has a very high thermal conductivity so that the total output power of Group III nitride devices on SiC is not limited by the thermal dissipation of the substrate. Sapphire is another common substrate for Group III nitrides and also has certain advantages, including being lower cost, having established manufacturing processes, and having good light-transmissive optical properties.

Different embodiments of the active LED structure can emit different wavelengths of light depending on the composition of the active layer and n-type and p-type layers. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 650 nm. In certain embodiments, the active LED structure may be configured to emit light that is outside the visible spectrum, including one or more portions of the ultraviolet (UV) spectrum. The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2500 Kelvin (K) to 10,000K. In certain embodiments, lumiphoric materials having cyan, green, amber, yellow, orange, and/or red peak wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material. In certain embodiments, a top surface of an LED chip may include lumiphoric material, while one or more side surfaces of an LED chip may be devoid of lumiphoric material. In certain embodiments, all or substantially all outer surfaces of an LED chip (e.g., other than contact-defining or mounting surfaces) may be coated or otherwise covered with one or more lumiphoric materials. In certain embodiments, one or more lumiphoric materials may be arranged on or over one or more surfaces of an LED chip in a substantially uniform manner. In other embodiments, one or more lumiphoric materials may be arranged on or over one or more surfaces of an LED chip in a manner that is non-uniform with respect to one or more of material composition, concentration, and thickness. In certain embodiments, the loading percentage of one or more lumiphoric materials may be varied on or among one or more outer surfaces of an LED chip. In certain embodiments, one or more lumiphoric materials may be patterned on portions of one or more surfaces of an LED chip to include one or more stripes, dots, curves, or polygonal shapes. In certain embodiments, multiple lumiphoric materials may be arranged in different discrete regions or discrete layers on or over an LED chip.

In certain embodiments, one or more lumiphoric materials may be provided as at least a portion of a wavelength conversion element or cover structure that is provided over an LED chip. Wavelength conversion elements or cover structures may include a support element and one or more lumiphoric materials that are provided by any suitable means, such as by coating a surface of the support element or by incorporating the lumiphoric materials within the support element. In some embodiments, the support element may be composed of a transparent material, a semi-transparent material, or a light-transmissive material, such as sapphire, SiC, silicone, and/or glass (e.g., borosilicate and/or fused quartz). Wavelength conversion elements and cover structures of the present disclosure may be formed from a bulk material which is optionally patterned and then singulated. In certain embodiments, the patterning may be performed by an etching process (e.g., wet or dry etching), or by another process that otherwise alters a surface, such as with a laser or saw. In certain embodiments, wavelength conversion elements and cover structures may be thinned before or after the patterning process is performed. In certain embodiments, wavelength conversion elements and cover structures may comprise a generally planar upper surface that corresponds to a light emission area of the LED package.

Wavelength conversion elements and cover structures may be attached to one or more LED chips using, for example, a layer of transparent adhesive. In certain embodiments, the layer of the transparent adhesive may include silicone with a refractive index in a range of about 1.3 to about 1.6 that is less than a refractive index of the LED chip on which the wavelength conversion element is placed. In various embodiments, wavelength conversion elements may comprise configurations such as phosphor-in-glass or ceramic phosphor plate arrangements. Phosphor-in-glass or ceramic phosphor plate arrangements may be formed by mixing phosphor particles with glass frit or ceramic materials, pressing the mixture into planar shapes, and firing or sintering the mixture to form a hardened structure that can be cut or separated into individual wavelength conversion elements.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of ultraviolet (UV) LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. In certain embodiments, a vertical geometry or lateral geometry LED chip may be configured as set forth in the commonly-assigned U.S. Pat. No. 9,461,201, which is hereby incorporated by reference herein. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In some embodiments, a lateral geometry LED chip may be mounted on a submount of an LED package such that the anode and cathode connections are on a face of the LED chip that is opposite the submount. In this configuration, wirebonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In certain embodiments, the flip-chip LED chip may be configured as described in commonly-assigned U.S. Patent Application Publication No. 2017/0098746, which is hereby incorporated by reference herein. In other embodiments, an active LED structure may be bonded to a carrier submount, and the growth substrate may be removed such that light may exit the active LED structure without passing through the growth substrate. In certain embodiments, an LED package may be configured as set forth in the following commonly-assigned U.S. patents, which are hereby incorporated by reference herein: U.S. Pat. Nos. 8,866,169; 9,070,850; 9,887,327; and 10,468,565.

According to aspects of the present disclosure LED packages may include one or more elements, such as lumiphoric materials, encapsulants, light-altering materials, lenses, and electrical contacts, among others, that are provided with one or more LED chips. In certain aspects, an LED package may include a support member, such as a submount or a leadframe. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. In certain aspects, the particles may have an index or refraction that is configured to refract light emissions in a desired direction. In certain aspects, light-reflective particles may also be referred to as light-scattering particles. A weight ratio of the light-reflective particles or scattering particles to a binder may comprise a range of about 1:1 to about 2:1. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

In certain embodiments, the light-altering material includes both light-reflective material and light-absorbing material suspended in a binder. A weight ratio of the light-reflective material to the binder may comprise a range of about 1:1 to about 2:1. A weight ratio of the light-absorbing material to the binder may comprise a range of about 1:400 to about 1:10. In certain embodiments, a total weight of the light-altering material includes any combination of the binder, the light-reflective material, and the light-absorbing material. In some embodiments, the binder may comprise a weight percent that is in a range of about 10% to about 90% of the total weight of the light-altering material. The light-reflective material may comprise a weight percent that is in a range of about 10% to about 90% of the total weight of the light-altering material. The light-absorbing material may comprise a weight percent that is in a range of about 0% to about 15% of the total weight of the light-altering material.

In further embodiments, the light-absorbing material may comprise a weight percent that is in a range of about greater than 0% to about 15% of the total weight of the light-altering material. In further embodiments, the binder may comprise a weight percent that is in a range of about 25% to about 70% of the total weight of the light-altering material. The light-reflective material may comprise a weight percent that is in a range of about 25% to about 70% of the total weight of the light-altering material. The light-absorbing material may comprise a weight percent that is in a range of about 0% to about 5% of the total weight of the light-altering material. In further embodiments, the light-absorbing material may comprise a weight percent that is in a range of about greater than 0% to about 5% of the total weight of the light-altering material.

In certain aspects, light-altering materials may be provided in a preformed sheet or layer that includes light-altering particles suspended in a binder. For example, light-altering particles may be suspended in a binder of silicone that is not fully cured to provide the preformed sheet of light-altering materials. A desired thickness or height of the preformed sheet may be provided by moving a doctor blade or the like across the sheet. The preformed sheet may then be positioned on and subsequently formed around an LED chip and/or a wavelength conversion element that is on the LED chip. For example, the preformed sheet may be laminated around the LED chip and/or wavelength conversion element and then the preformed sheet may be fully cured in place. One or more portions of the preformed sheet may then be removed from a primary light-emitting face of the LED chip and/or wavelength conversion element. In this manner, light-altering materials may be formed along peripheral edges or sidewalls of the LED chip and wavelength conversion element with thicknesses not previously possible with conventional dispensing techniques typically used to form light-altering materials. Additionally, light-altering materials may be provided without needing conventional submounts or lead frames as support for conventional dispensing and/or molding techniques. In this regard, LED devices with light-altering materials may be provided with reduced footprints suitable for closely-spaced LED arrangements.

Aspects of the present disclosure are provided that include optical arrangements for cover structures of LED packages for improving or otherwise tailoring emission characteristics. Such cover structures may include hard and mechanically robust structures that are positioned over one or more LED chips within an LED package. A cover structure may be configured to provide protection from environmental exposure to underlying portions of an LED package, thereby providing a more robust LED package that is well suited for applications that require high power with increased light intensity, contrast, and reliability, such as interior and exterior automotive applications. Cover structures may comprise host materials such as glass or ceramics that provide mechanically robust structures for environmental protection. Such cover structures may be fabricated by providing sheets of glass frit or ceramic precursor materials, pressing the sheets into planar shapes, and firing or sintering to form hardened structures that can be cut or separated. The resulting cover structure may be referred to as a glass plate or a ceramic plate. When lumiphoric materials, such as phosphors, are included in the glass frit or ceramic precursor materials, the resulting cover structures may be referred to as phosphor-in-glass plates or ceramic phosphor plates. Conventional phosphor-in-glass plates or ceramic phosphor plates typically have phosphor materials evenly distributed throughout the plates. While this may provide suitable brightness of LED package emissions, the conventional plates can tend to exhibit non-uniformity of emissions due to poor color over angle for light that is converted.

According to aspects of the present disclosure, cover structures with tailored optical arrangements are disclosed that may provide desired emission characteristics including brightness, uniformity, and emission patterns for associated LED packages. In certain aspects, cover structures may be fabricated by providing thin sheets of precursor materials, (e.g., glass frit, ceramic materials, binders and the like) where one or more of the thin sheets are configured with different optical arrangements than other ones of the thin sheets in order to provide different optical characteristics. The thin sheets may then be pressed and fired together to form a cover structure with a host material of glass and/or ceramic that is embedded with optical arrangements that vary in one or more of a horizontal and a vertical direction.

Optical arrangements as described herein may include one or more lateral and vertical arrangements of different regions of optical materials within the cover structure that are configured to interact with light in a different manner than the host material of the cover structure. As used herein, optical materials may include lumiphoric materials, materials with different indexes of refraction, light-scattering materials, and light-diffusing materials individually or in various combinations with one another. Various configurations of optical materials may be provided in each of the sheets before firing to provide a corresponding cover structure that provides one or more of improved light output, increased light extraction, improved emission uniformity, and improved emission contrast for the LED package.

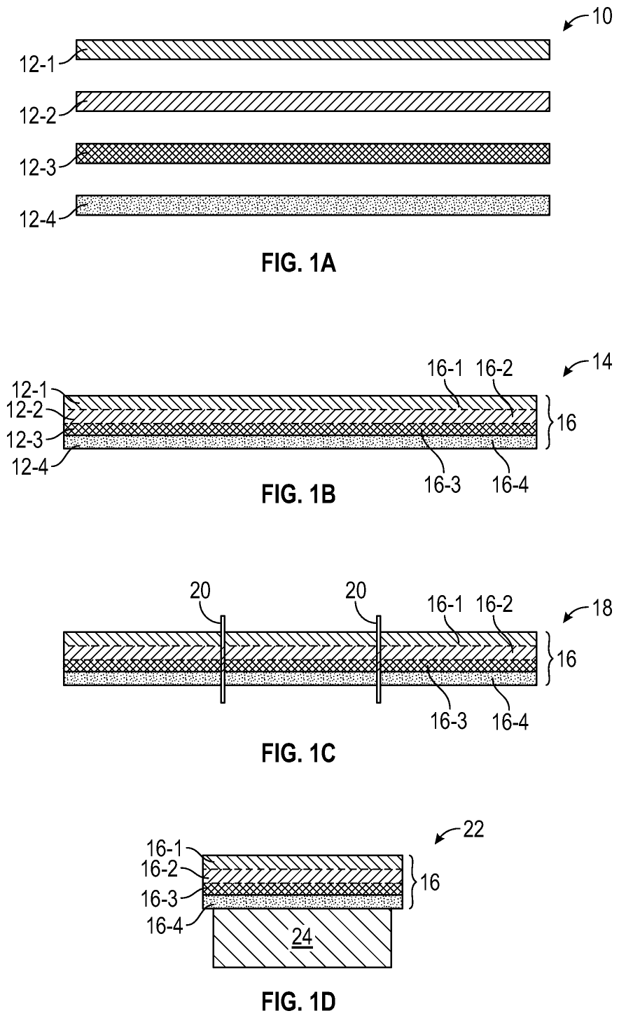

FIGS. 1A-1D illustrate an exemplary fabrication process for forming cover structures with varying optical arrangements according to principles of the present disclosure. FIG. 1A illustrates a cross-sectional view at a first fabrication step 10 where multiple sheets 12-1 to 12-4 of precursor materials are provided that have different optical arrangements from one another. In certain embodiments, a precursor material for a glass plate may comprise glass frit and a corresponding binder, and a precursor material for a ceramic plate may comprise ceramic materials and a corresponding binder. The precursor materials may typically be formed as a slurry that is dried to form the corresponding sheets 12-1 to 12-4. As described herein, the sheets 12-1 to 12-4 may sometimes be referred to as green sheets that refer to composite sheets before firing. By way of example, each of the sheets 12-1 to 12-4 may comprise an optical material, such as a lumiphoric material, that is provided with different loading amounts or quantities within the precursor material, such as progressively decreasing quantities of lumiphoric material from the first sheet 12-1 toward the last sheet 12-4. Depending on the desired emission characteristics, the loading amounts of lumiphoric materials may be provided in other arrangements, including progressively increasing amounts from the first sheet 12-1 toward the last sheet 12-4, or distributions increasing and decreasing from the first sheet 12-1 toward the last sheet 12-4. While FIG. 1A is described in the context of lumiphoric materials, the sheets 12-1 to 12-4 may include one or more combinations with other optical arrangements of optical materials, including arrangements of materials with different indexes of refraction, light-scattering materials, and light-diffusing materials separately or in combination with lumiphoric materials. Additionally, while FIG. 1A is illustrated with four sheets 12-1 to 12-4, the concepts disclosed may be applicable to any number of sheets. In certain embodiments, the number of sheets 12-1 to 12-4 comprises a range from 2 to 10 sheets, or a range from 2 to 8 sheets, or a range from 2 to 6 sheets. Thickness ranges for the sheets 12-1 to 12-4 may be tailored to particular applications, with some ranges being provided in a range from 20 microns (μm) to 500 μm, or in a range from 20 μm to 300 μm, or in a range from 50 μm to 250 μm, or in a range from 100 μm to 200 μm.

FIG. 1B illustrates a cross-sectional view at a second fabrication step 14 where the multiple sheets 12-1 to 12-4 of FIG. 1A are pressed together and fired to form a cover structure 16. As illustrated, each of the sheets 12-1 to 12-4 forms a corresponding region or sublayer 16-1 to 16-4 of the cover structure 16. During firing, binder materials of the sheets 12-1 to 12-4 are reduced and/or removed, thereby providing the cover structure 16 as a rigid structure with the various sublayers 16-1 to 16-4 having different optical characteristics. As binder materials are removed during firing, the cover structure 16 may comprise a compressed thickness relative to a sum of the respective sheets 12-1 to 12-4 before pressing and firing. By way of example, if each of the four sheets 12-1 to 12-4 was provided with an initial thickness of 200 μm for a total of 800 μm when stacked, the resulting cover structure 16 may have a final thickness in a range from 400 μm to 500 μm after firing. After firing, the cover structure 16 may optionally be subjected to a removal process, such as polishing, that can reduce the thickness of the cover structure 16 further to a targeted range. In certain embodiments, thicknesses of cover structures 16 intended for LED package applications, may have a final thickness in a range from 25 μm to 500 μm, or in a range from 25 μm to 300 μm, or in a range from 100 μm to 250 μm.

FIG. 1C illustrates a cross-sectional view at a third fabrication step 18 where the cover structure 16 may be singulated. In certain embodiments, singulation may involve sub-dividing the cover structure 16 into a number of smaller cover structures 16. As illustrated in FIG. 1C, two vertical separation lines 20 are superimposed where the cover structure 16 may be divided. The singulation process may comprise dicing with one or more of a saw blade and a laser along the separation lines 20. In this manner, lateral dimensions of the cover structure 16 may be tailored to a particular LED package.

FIG. 1D illustrates a cross-sectional view at a fourth fabrication step 22 where the cover structure 16 is provided in a light receiving arrangement with an LED chip 24. In certain embodiments, the cover structure 16 may be positioned over the LED chip 24. The cover structure 16 may be attached to the LED chip 24 by way of a transparent adhesive, such as a thin layer of silicone. As will be later described in more detail, the cover structure 16 may be attached or otherwise in contact with other elements of exemplary LED packages, including but not limited to encapsulation layers that may be provided on the LED chip 24 and/or light-altering materials that may be provided around peripheral edges of the LED chip 24. As illustrated, the cover structure 16 may comprise various sublayers 16-1 to 16-4 having different optical characteristics. In the example provided by FIG. 1D, the optical characteristics are varied in a vertical direction relative to an interface between the cover structure 16 and the LED chip 24.

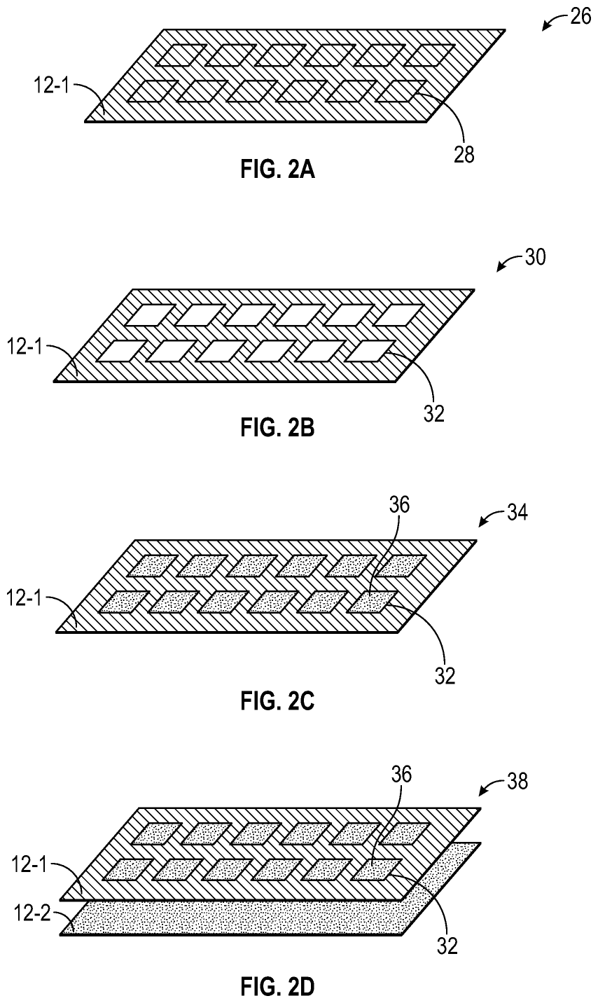

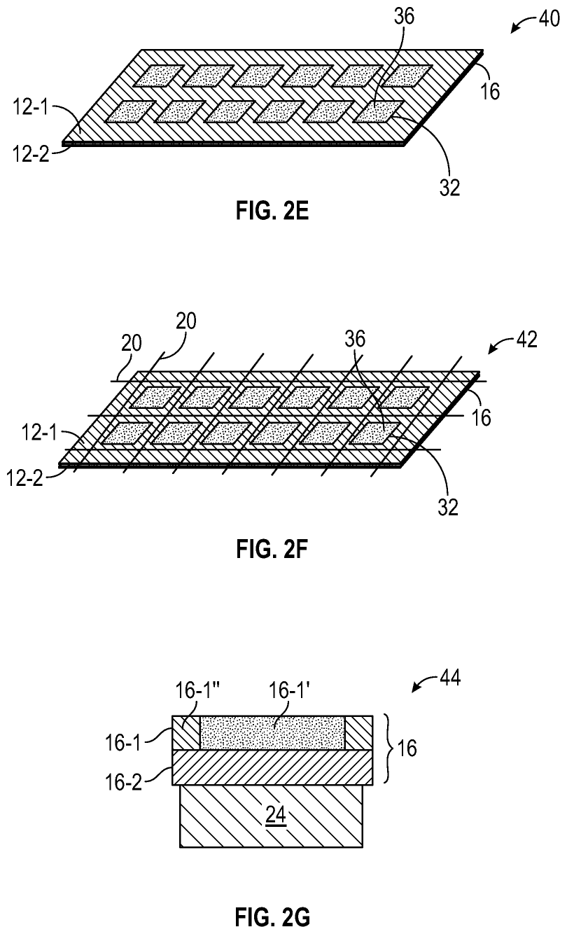

While the embodiments of FIGS. 1A-1D illustrate configurations where arrangements of optical materials may be varied in a vertical direction, the principles of the present disclosure are applicable to other configurations, including horizontally varied arrangements of optical materials and both vertically and horizontally varied arrangements of optical materials. In this regard, FIGS. 2A-2G illustrate an exemplary fabrication process for forming cover structures where arrangements of optical materials may be varied in one or more of vertical and horizontal configurations according to principles of the present disclosure.

FIG. 2A is a perspective view of a first fabrication step 26 where the first sheet 12-1 has been patterned with a number of features 28. The features 28 may be defined by one or more of lasering, micromachining, and the like. As will be later described in more detail, the features 28 may correspond with sub-regions or sublayers of the first sheet 12-1 that may be provided with different optical characteristics than other portions of the first sheet 12-1. While the features 28 are illustrated as generally rectangular in the perspective view of FIG. 2A, each of the features 28 may be patterned to form any number of shapes, including circular, hexagonal, and other geometric shapes, as well as stripes and dot patterns, depending on the desired emission characteristics of the resulting LED package.

FIG. 2B is a perspective view of a second fabrication step 30 where portions of the first sheet 12-1 within outlines of the features 28 of FIG. 2A are removed to form openings or wells 32 of the first sheet 12-1. In certain embodiments, the portions of the first sheet 12-1 within outlines of the features 28 of FIG. 2A may be punched out or otherwise mechanically removed. As illustrated, the sheet 12-1 is thereby formed with an array of wells 32.

FIG. 2C is a perspective view of a third fabrication step 34 where the wells 32 are filled with a first optical material 36 having a different optical characteristic than the remaining portions of the first sheet 12-1. For example, the first optical material 36 may comprise one or more of lumiphoric materials, materials with different indexes of refraction, light-scattering materials, and light-diffusing materials separately or in combination with one another that are provided in different quantities than remaining portions of the first sheet 12-1. In certain embodiments, the first optical material 36 may be mixed in a slurry with the same type of precursor materials (e.g., glass frit, ceramic, and the like) as the first sheet 12-1.

FIG. 2D is a perspective view of a fourth fabrication step 38 where the first sheet 12-1 with filled wells 32 is provided over the second sheet 12-2 before being pressed together. In various configurations, the second sheet 12-2 may be configured with a different optical arrangement than the first sheet 12-1. By way of example, the second sheet 12-2 may comprise a second optical material, such as a same lumiphoric material as the first optical material 36 but with a different loading amount. In other embodiments, the second optical material of the second sheet 12-2 may comprise a different lumiphoric material that provides a different emission color than the lumiphoric material of the first optical material 36. FIG. 2E is a perspective view of a fifth fabrication step 40 where the first and second sheets 12-1, 12-2 are pressed together and fired to form a cover structure 16 in a manner similar as described above for FIG. 1B.

FIG. 2F illustrates a cross-sectional view at a sixth fabrication step 42 where the cover structure 16 may be singulated. The singulation may involve sub-dividing the cover structure 16 into a number of smaller cover structures 16 along the separation lines 20. In certain embodiments, the separation lines 20 may be arranged to provide at least one of the wells 32 within each individual cover structure 16.

FIG. 2G illustrates a cross-sectional view at a seventh fabrication step 44 where the cover structure 16 is provided in a light receiving arrangement with the LED chip 24. In certain embodiments, the cover structure 16 may be positioned or attached to the LED chip 24 by way of a transparent adhesive, such as a thin layer of silicone. As will be later described in more detail, the cover structure 16 may be attached or otherwise in contact with other elements of exemplary LED packages, including but not limited to encapsulation layers that may be provided on the LED chip 24 and/or light-altering materials that may be provided around peripheral edges of the LED chip 24. Based on the configuration of the sheets 12-1 to 12-2 in FIGS. 2A-2F, the cover structure 16 may comprise various sublayers 16-1, 16-2 having different optical characteristics. For example, the sublayer 16-1 corresponds with the first sheet 12-1 and the sublayer 16-2 corresponds with the second sheet 12-2. In this regard, the first sublayer 16-1 includes a first region 16-1′ that corresponds with the first optical material 36 of the filled wells 32 of FIG. 2F. The first sublayer 16-1 further includes a second region 16-1″ that corresponds to the remainder of the first sheet 12-1 that is outside of the filled wells 32, such as the host material of glass and/or ceramic. In such an arrangement, the second region 16-1″ is arranged to laterally surround the first region 16-1′. In a similar manner, the second sublayer 16-2 corresponds with the second sheet 12-2. In certain embodiments, the second optical material of the second sheet 12-2 is provided uniformly throughout the second sublayer 16-2. In the example provided by FIG. 2G, the optical characteristics provided by the first and second sublayers 16-1, 16-2 are varied in both a vertical direction relative to an interface between the cover structure 16 and the LED chip 24 and a lateral direction relative to the interface.

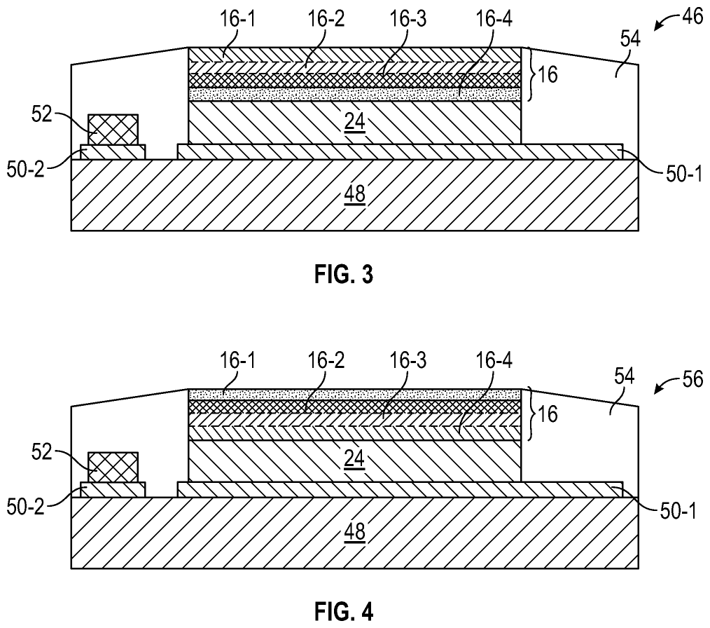

FIG. 3 is a cross-sectional view of an LED package 46 that includes the cover structure 16 provided over the LED chip 24 according to principles of the present disclosure. The LED chip 24 may be mounted on a submount 48. The LED chip 24 may be mounted to and electrically coupled to one or more electrical traces 50-1, 50-2 that are provided on the submount 48. In certain embodiments, the LED chip 24 may be flip-chip mounted such that an anode and a cathode of the LED chip 24 are mounted to and electrically coupled with different ones of the electrical traces 50-1, 50-2. In certain embodiments, the electrical traces 50-1, 50-2 and the submount 48 may embody a lead frame structure that supports the LED chip 24. Additionally, an electrical overstress device 52 may be mounted to and electrically coupled to one or more of the electrical traces 50-1, 50-2 to provide protection from electrical overstress events where currents or voltages exceed maximum ratings for the LED chip 24. The electrical overstress device 52 may comprise an electrostatic discharge (ESD) chip such as a Zener diode.

Light that is generated by the active region of the LED chip 24 may be omnidirectional in nature and LED packages are typically designed with features that are arranged to redirect light from the active region toward a desired emission direction. For example, a desired emission direction for the LED package 46 of FIG. 3 may be perpendicular with an interface between the LED chip 24 and the submount 48 or the electrical traces 50-1, 50-2. In certain embodiments, a light-altering material 54 may be arranged around peripheral edges of the LED chip 24 to reflect or otherwise redirect light toward the desired emission direction. In various configurations, the light-altering material 54 may comprise light-altering particles such as one or more of fused silica, fumed silica, zinc oxides, tantalum oxides, zirconium oxides, niobium oxides, yttrium oxides, alumina, glass beads, and TiO₂ that are suspended or embedded within a binder such as silicone or epoxy.

With further reference to FIG. 3, the cover structure 16 may be mounted or otherwise attached over the LED chip 24 and at least some peripheral edges of the cover structure 16 may be surrounded by the light-altering material 54. As illustrated, the cover structure 16 may be provided with sublayers 16-1 to 16-4 that are formed according to the fabrication process described for FIGS. 1A-1D. In this manner, each of the sublayers 16-1 to 16-4 may comprise optical materials having different loading amounts or concentrations. In certain embodiments, the optical materials comprise a same lumiphoric material that is provided with progressively decreasing quantities in the cover structure 16 from the sublayer 16-4 toward the sublayer 16-1. By arranging higher quantities of the lumiphoric material closer to the LED chip 24, improved thermal dissipation of heat for such lumiphoric materials may be realized, thereby improving the lifetime of the LED package 46. Additionally, arranging higher quantities of the lumiphoric material closer to the LED chip 24 may further improve emission uniformity for the LED package 46 by providing improved color over angle of emissions. While four sublayers 16-1 to 16-4 are illustrated, the principles disclosed are applicable to any number of sublayers, including a range from 2 to 10, or a range from 2 to 8, or a range from 2 to 6 sublayers.

FIG. 4 is a cross-sectional view of an LED package 56 that is similar to the LED package 46 of FIG. 3 but includes a progressively increasing quantity of the lumiphoric material in a direction away from the LED chip 24. In this manner, the order of the lumiphoric material loading in each of the sublayers 16-1 to 16-4 may be reversed from FIG. 3 such that the highest quantity of lumiphoric material is arranged farthest away from the LED chip 24. By positioning the highest quantity of lumiphoric material at or near an outer surface of the cover structure 16, light-scattering associated with light interactions with the lumiphoric material may be increased at light-emitting surfaces of the LED package 56. In this regard, the LED package 56 may exhibit improved emission uniformity and color mixing for certain applications.

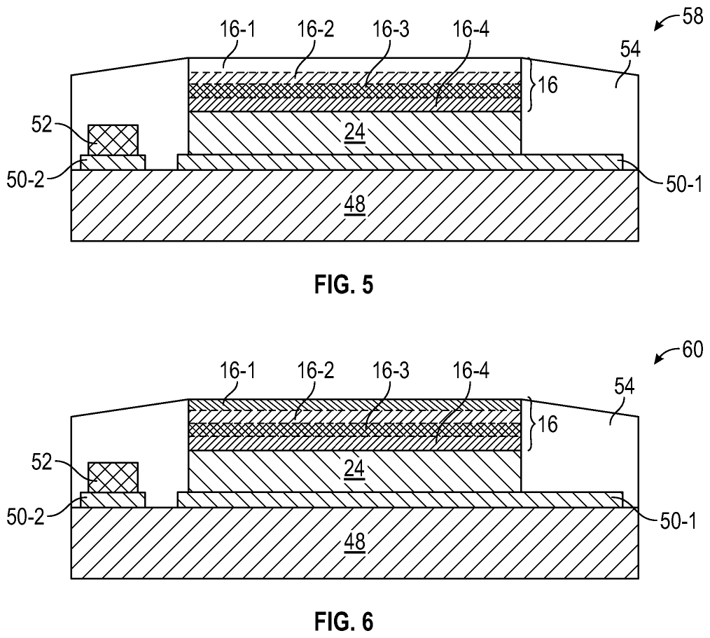

FIG. 5 is a cross-sectional view of an LED package 58 that is similar to the LED package 46 of FIG. 3 but includes different lumiphoric materials in one or more of the sub-layers 16-1 to 16-4. By applying the fabrication process described above for FIGS. 1A-1D, different ones of the sublayers 16-1 to 16-4 may be provided with different lumiphoric materials that provide wavelength conversions having different peak emissions of light. In certain embodiments, the sublayer 16-4 that is arranged closest to the LED chip 24 may comprise a lumiphoric material that provides converted wavelengths in a highest peak wavelength range compared to the other sublayers. By way of example, the sublayer 16-4 may comprise red lumiphoric materials, the sublayer 16-3 may comprise yellow lumiphoric materials, and the sublayer 16-2 may comprise green lumiphoric materials. The sublayer 16-1 may be devoid of lumiphoric materials, or the sublayer 16-1 may comprise yellow and/or green lumiphoric materials with different quantities than the sublayers 16-2, 16-3. In certain embodiments, the peak wavelength range of lumiphoric materials within the cover structure 16 is arranged to progressively decrease with increasing distance in a direction away from the LED chip 24. Red lumiphoric materials may have excitation spectrums that overlap with emission spectrums of yellow or green lumiphoric materials. As such, light that may initially be converted by the yellow or green lumiphoric materials may subsequently be converted again by the red lumiphoric material, thereby limiting emission efficiencies. In this regard, the LED package 58 may exhibit improved emission efficiency by providing the red lumiphoric material between the yellow and green lumiphoric materials and the LED chip 24 in order to reduce interactions between yellow/green wavelengths of light and the red lumiphoric materials.

FIG. 6 is a cross-sectional view of an LED package 60 that is similar to the LED package 58 of FIG. 5 for embodiments where the sublayer 16-1 includes light-scattering particles and/or light-diffusing particles. In certain embodiments, the sublayer 16-1 may include light-scattering materials while being devoid of lumiphoric materials. As illustrated, the sublayer 16-1 is configured as the topmost sublayer of the cover structure 16. In this manner, the outer surface of the sublayer 16-1 forms the light emitting surface for the LED package 60. By providing an optical material of light-scattering and/or light-diffusing particles in the sublayer 16-1, wavelengths of light from the LED chip 24 and wavelengths of light that have been converted by the lumiphoric materials of the sublayers 16-2 to 16-4, may encounter increased scattering and/or diffusion in the sublayer 16-1 before exiting the LED package 60. In this regard, aggregate emissions from the LED package 60 may exhibit improved color mixing.

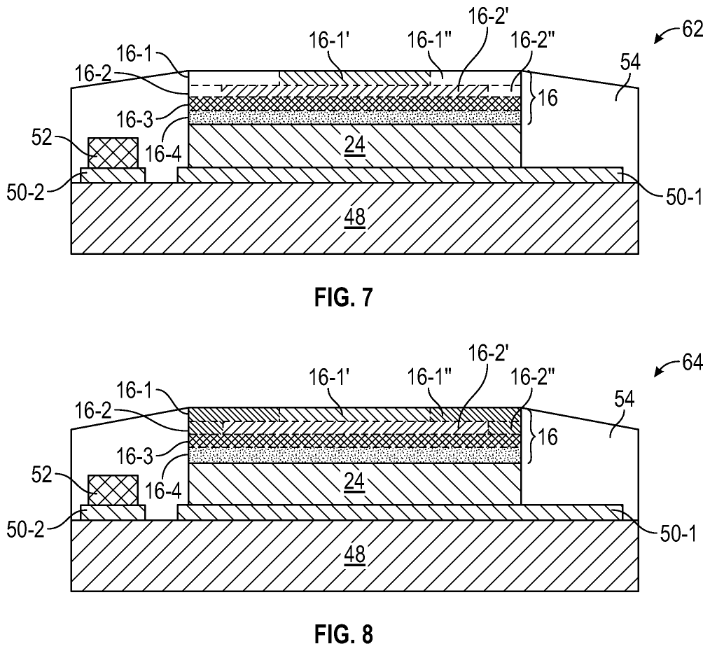

While the embodiments described above for FIGS. 3-6 provide optical materials that may be distributed throughout various sublayers, the principles of the present disclosure are applicable to other arrangements of optical materials within sublayers. For example, the fabrication steps described above for FIGS. 2A-2G may be utilized to provide cover structures where one or more sublayers include subregions of optical materials. In this regard, FIGS. 7-10 below provide various examples of LED packages that include at least one sublayer that is configured with a subregion of optical material.

FIG. 7 is a cross-sectional view of an LED package 62 that is similar to the LED package 46 of FIG. 3 and includes at least one sublayer with a subregion of optical material. In FIG. 7, the sublayer 16-1 may be laterally subdivided in a number of subregions 16-1′, 16-1″ that are arranged with different optical characteristics. For example, the subregion 16-1′ may comprise a lumiphoric material and the subregion 16-1″ may be devoid of the lumiphoric material. In certain embodiments, the subregion 16-1′ may be laterally surrounded by the subregion 16-2″ such that the subregion 16-1′ is centrally aligned over the LED chip 24. In a similar manner, the sublayer 16-2 may be laterally subdivided in a number of subregions 16-2′, 16-2″ that are arranged with different optical characteristics. In certain embodiments, the subregion 16-2′ comprises the same lumiphoric material as the subregion 16-1′ and the subregions 16-2″ may be devoid of the lumiphoric material. The sublayers 16-3, 16-4 may be provided with quantities of the lumiphoric material as previously described for FIG. 3. As illustrated, the subregion 16-2′ is formed with a lateral width that is less than a lateral width of the underlying sublayers 16-3, 16-4, and the subregion 16-1′ is formed with a lateral width that is less than the lateral width of the subregion 16-2″. In this manner, lateral widths of the lumiphoric materials within the cover structure 16 may decrease in a direction away from the LED chip 24. In certain applications, this configuration may provide improved color over angle uniformity for the LED package 62 by reducing wavelength conversions along a perimeter of the cover structure 16. In various embodiments, the lumiphoric materials of the sublayers 16-1 to 16-4 may be arranged according to any of the configurations described above for FIGS. 3-6.

FIG. 8 is a cross-sectional view of an LED package 64 that is similar to the LED package 62 of FIG. 7 and where the subregions 16-1″ and 16-2″ include light-scattering particles and/or light-diffusing particles. By providing an optical material of light-scattering and/or light-diffusing particles in the subregions 16-1″ and 16-2″ that respectively surround the associated subregions 16-1′ and 16-2′, light from the LED chip 24 and light that is converted by lumiphoric materials in any of the sublayers 16-1 to 16-4 may exhibit improved scattering at high emission angles, thereby providing further improvements to color over angle uniformity. In further embodiments, light-scattering and/or light-diffusing particles may also be provided in the subregions 16-1′ and 16-2′, but in reduced amounts compared with the subregions 16-1″ and 16-2″. As such, one or more of the sublayers 16-1, 16-2 of the cover structure 16 may include laterally or horizontally varied arrangements of optical materials (e.g., lumiphoric materials and light-scattering and/or light-diffusing particles). In various embodiments, the lumiphoric materials of the sublayers 16-1 to 16-4 may be arranged according to any of the configurations described above for FIGS. 3-6. In this manner, the cover structure 16 may include both vertically and horizontally varied arrangements of various optical materials.

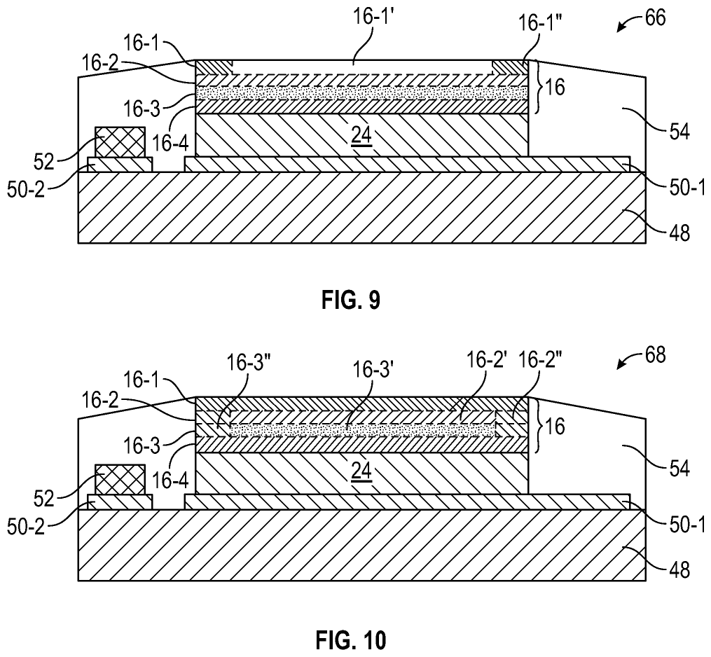

FIG. 9 is a cross-sectional view of an LED package 66 that is similar to the LED package 60 of FIG. 6 and where the sublayer 16-1 includes the subregions 16-1′, 16-1″ and the light-scattering and/or light-diffusing particles are only provided in the subregion 16-1″. As previously described for FIG. 6, the sublayer 16-4 may include a red lumiphoric material, the sublayer 16-3 may include a yellow lumiphoric material, and the sublayer 16-2 may include a green lumiphoric material. By providing the light-scattering and/or light-diffusing particles only in the subregion 16-1″ that laterally surrounds the subregion 16-1′, improved color mixing of light from the LED chip 24 and the red, yellow, and green lumiphoric materials may be provided along perimeter portions of the cover structure 16 for improved color over angle uniformity.

FIG. 10 is a cross-sectional view of an LED package 68 that is similar to the LED package 60 of FIG. 6 and where one or more sublayers 16-2, 16-3 include laterally or horizontally varied lumiphoric materials. In FIG. 10, a first subregion 16-3′ of the sublayer 16-3 includes a first lumiphoric material and a first subregion 16-2′ of the sublayer 16-2 includes a different lumiphoric material. A second subregion 16-3″ of the sublayer 16-3 that laterally surrounds the first subregion 16-3′ may include yet another lumiphoric material that is either compositionally different than the first and second lumiphoric materials or is compositionally the same as one of the first and second lumiphoric materials, but with a different loading quantity. By way of example, the subregion 16-3′ may comprise a yellow lumiphoric material, the subregion 16-2′ may comprise a green lumiphoric material, and one or more of the subregions 16-2″ and 16-3″ may comprises the yellow lumiphoric material with a reduced loading compared to the subregion 16-3′. By providing reduced quantities of the yellow lumiphoric material around a perimeter of one or more of the sublayers 16-2, 16-3, the color over angle and/or color mixing may be further tailored to desired emission characteristics for the LED package 68. In certain embodiments, the sublayer 16-4 may include a red lumiphoric material and the sublayer 16-1 may comprise light-scattering and/or light-diffusing particles.

While the above-described embodiments provide various arrangements of vertically and/or horizontally varied optical materials that include lumiphoric materials and/or light-scattering and/or light-diffusing particles, the principles of the present disclosure are also applicable for providing cover structures with vertically and/or horizontally varied index of refraction characteristics. In this regard, host materials and/or additives to the host materials may be varied from sheet to sheet or within certain sheets that may provide varying index of refraction characteristics in resulting cover structures. In certain embodiments, the additives may include scattering particles such as one or more of TiO₂, ZnO, and ZrO₂ that are mixed with host materials such as glass frit and/or ceramic materials.

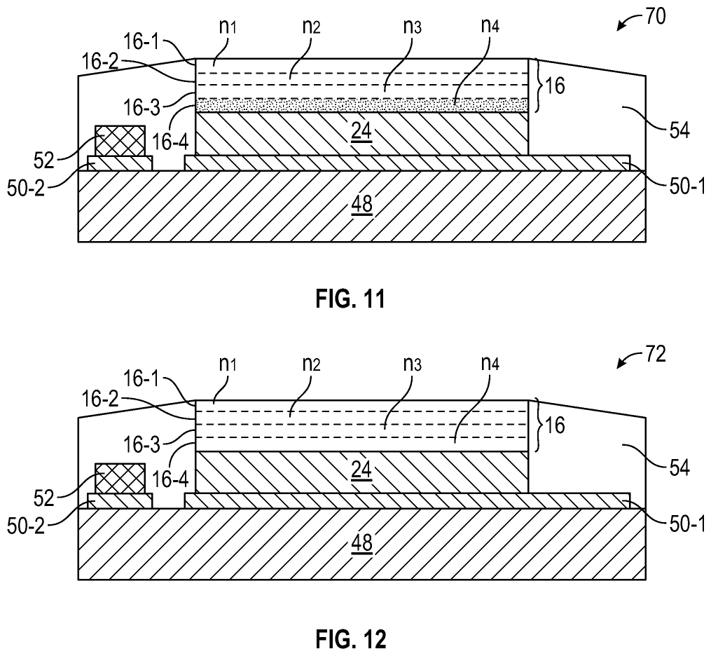

FIG. 11 is a cross-sectional view of an LED package 70 that is similar to the LED package 46 of FIG. 3 but where one or more of the sublayers 16-1 to 16-4 include different index of refraction characteristics relative to one another. In FIG. 11, the sublayer 16-1 is configured with a first index of refraction n1, the sublayer 16-2 is configured with a second index of refraction n2, the sublayer 16-3 is configured with a third index of refraction n3, and the sublayer 16-4 is configured with a fourth index of refraction n4. In certain embodiments, each index of refraction n1 to n4 comprises a different index of refraction from one another. For example, the index of refraction n4 that is closest to the LED chip 24 may comprise a highest value and the index of refraction n1 that is farthest from the LED chip 24 may comprise a lowest value. The indexes of refraction n2 and n3 may be provided with intermediate values that progressively decrease from n4 to n1. In this manner, the cover structure 16 may be provided with varying index of refraction values that decrease in a direction from the LED chip 24 toward an air interface above the cover structure 16 to reduce total internal reflection and increase brightness. By way of example, the index of refraction values for n1, n2, n3, and n4 may comprise values of 1.5, 1.55, 1.6, and 1.65 in particular embodiments. Additionally, one or more of the sublayers 16-1 to 16-4 may also include a lumiphoric material as previously described. For example, the sublayer 16-4 may comprise a lumiphoric material while one or more of the sublayers 16-1 to 16-3 may be devoid of lumiphoric materials.

FIG. 12 is a cross-sectional view of an LED package 72 that is similar to the LED package 70 of FIG. 11 for embodiments where the LED package 72 is devoid of lumiphoric materials and where one or more of the sublayers 16-1 to 16-4 include different index of refraction characteristics relative to one another. In this manner, the LED package 72 may be configured the same as the LED package 70 of FIG. 11, but without any lumiphoric materials present. Such a configuration may provide emissions for the LED package 70 that are not subjected to wavelength conversions. For example, the LED chip 24 may embody a single LED chip that provides monochromatic emissions (e.g., blue, green, or red, among others). In other examples, the LED chip 24 may embody multiple LED chips on the submount 48 that are underneath the cover structure 16, where one or more of the multiple LED chips are configured to provide different monochromatic emissions (e.g., one or more combinations of blue, green, and red, among others). In still further examples, the LED chip 24 may embody a monolithic LED chip that includes a plurality of active regions. The plurality of active regions may be defined partially or completely through the monolithic LED chip.

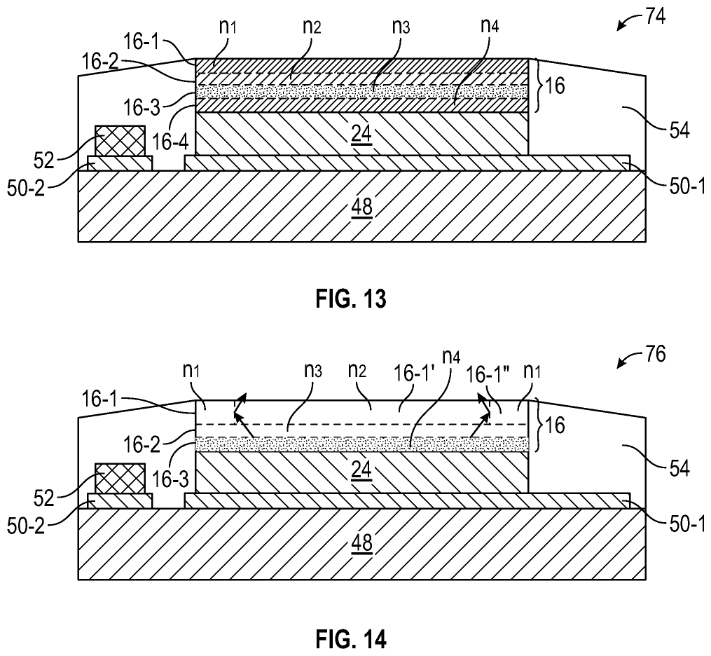

FIG. 13 is a cross-sectional view of an LED package 74 that is similar to the LED package 70 of FIG. 11 for embodiments where multiple ones of the sublayers 16-1 to 16-4 include lumiphoric materials that differ from one another and at least one of the sublayers 16-1 to 16-4 includes a light-scattering and/or light-diffusing material. In the embodiment illustrated in FIG. 13, the sublayers 16-1 to 16-4 may be configured in a similar manner as described for FIG. 6. In this regard, the sublayer 16-4 may comprise a red lumiphoric material, the sublayer 16-3 may comprise a yellow lumiphoric material, the sublayer 16-2 may comprise a green lumiphoric material, and the sublayer 16-1 may comprise light-scattering and/or light-diffusing materials. By providing the progressively decreasing index of refraction values from n4 near the LED chip 24 to n1 near an emission surface of the cover structure 16, reduction in internal reflection, increased brightness, and increased color mixing may be realized.

FIG. 14 is a cross-sectional view of an LED package 76 that is similar to the LED package 70 of FIG. 11 for embodiments where index of refraction values may also be varied laterally within one or more of the sublayers 16-1 to 16-3. In FIG. 14, the subregion 16-1′ of the sublayer 16-1 is provided with the second index of refraction n2 and the subregion 16-1″ that laterally surrounds the subregion 16-1′ is provided with the first index of refraction n1. Additionally, the sublayer 16-3 may comprise the fourth index of refraction n4 and the sublayer 16-2 may comprise the third index of refraction n3. By way of example, the index of refraction values for n1, n2, n3, and n4 may comprise steadily graded values (e.g., 1.5, 1.55, 1.6, and 1.65) in certain embodiments. By providing the lowest index of refraction n1 along a perimeter of the cover structure 16 and near an exterior of the LED package 76, laterally emitting light within the cover structure 16 may be redirected toward a desired emission direction as shown by the superimposed arrows in FIG. 14.

Embodiments of the present disclosure have been described that provide cover structures with horizontally and/or or vertically varied optical materials that are determined by configurations of sheets before pressing and firing. In additional embodiments, horizontally and/or or vertically varied optical materials may be provided by fabrication steps that occur after pressing and firing of cover structures. For example, cover structures may be subjected to subtractive processes such as micromachining, patterned etching, laser etching, and the like that selectively remove one or more portions of the cover structures. Such selective removal steps may be provided singularly or in combination with varying sheet arrangements to provide varied optical materials in resulting cover structures. The selective removal steps may be performed before or after a cover structure is attached to a corresponding LED package. In certain embodiments, the cover structure may be attached to the LED package and brightness and/or uniformity of emissions from the LED package may then be characterized. After characterization, one or more portions of the cover structure may be selective removed to tailor or refine the emission characteristics.

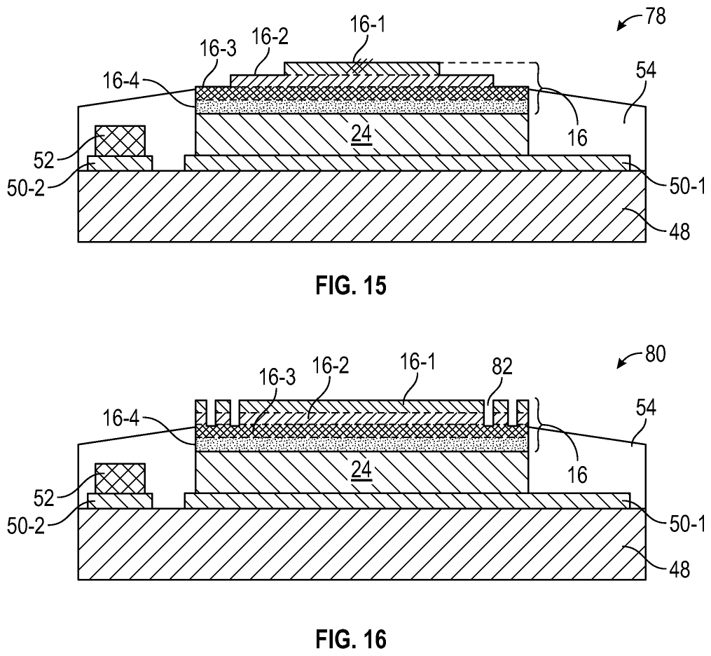

FIG. 15 is a cross-sectional view of an LED package 78 that is similar to the LED package 62 of FIG. 7 where one or more lateral portions of the cover structure 16 have been selectively removed. As illustrated, a lateral width of the sublayer 16-2 is smaller than a lateral width of the sublayers 16-3 and 16-4, and a lateral width of the sublayer 16-1 is even smaller than the lateral width of the sublayer 16-2. In certain embodiments, each of the sublayers 16-1 to 16-4 may comprise a same lateral width after firing of the cover structure 16. In one or more subsequent steps, lateral portions of each of the sublayers 16-1 and 16-2 may be selectively removed. For example, one or more of micromachining, patterned etching, laser etching, and the like may be applied to the cover structure 16 to arrive at the final structure as illustrated in FIG. 15. Selective removal of portions of the cover structure 16 may be performed before or after the cover structure 16 is attached to the LED package 78.

FIG. 16 is a cross-sectional view of an LED package 80 that is similar to the LED package 78 of FIG. 15 where one or more portions of the cover structure 16 have been selectively removed to form one or more features 82 in surfaces of the cover structure 16. The one or more features 82 may comprise openings or wells where localized portions of the cover structure 16 have been selectively removed from a surface of the cover structure 16. The one or more features 82 may be provided in lateral portions of the cover structure 16 and/or along central portions of the cover structure 16 depending on desired emission characteristics for the LED package 80. While the one or more features 82 are illustrated as extending through the sublayers 16-1 and 16-2, the one or more features 82 may extend to different depths within the cover structure 16 and different ones of the features 82 may extend to different depths from one another. In this regard, the cover structure 16 is able to be precisely tuned to provide target emission characteristics after the cover structure 16 has initially been formed.

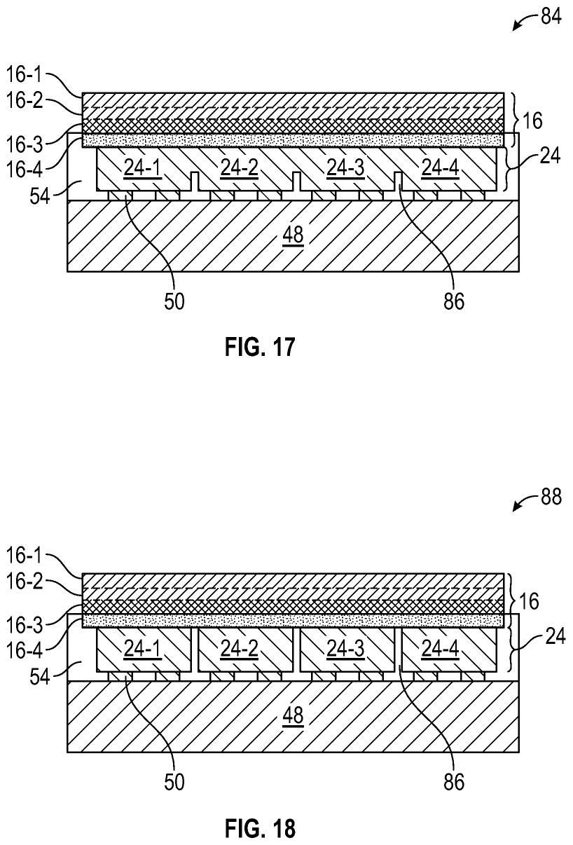

The LED chip 24 illustrated in any of the preceding FIGS. 1A, 2G, and 3-16 may embody any number of LED chip configurations, including a single LED chip, multiple LED chips, and a monolithic LED chip. For multiple LED chip embodiments, each of the LED chips may be configured to provide emissions having a same peak wavelength, or a plurality of different peak wavelengths to provide a multiple color LED package. For monolithic LED chip embodiments, an exemplary monolithic LED chip may include a plurality of active regions that are defined from a common active region. The plurality of active regions may be defined partially through the monolithic LED chip such that one or more portions of the LED chip provide a common structure for the plurality of active regions. In other embodiments, the plurality of active regions may be defined entirely through the monolithic LED chip. In this regard, FIGS. 17 and 18 are provided to illustrated various configurations of multiple LED chip and monolithic LED chip configurations.

FIG. 17 is a cross-sectional view of an LED package 84 that is similar to the LED package 46 of FIG. 3 for embodiments where the LED chip 24 is a monolithic LED chip. As illustrated in FIG. 17, the LED chip 24 may be subdivided into a number of LED regions 24-1 to 24-4. The LED regions 24-1 to 24-4 may embody individual portions of the LED chip 24 that include separately defined emitting junctions of the overall LED chip 24. A number of recesses or streets 86 may be defined partially through the LED chip 24 to define the LED regions 24-1 to 24-4. As illustrated, the streets 86 are arranged to partially extend through the LED chip 24, thereby leaving at least a portion of the LED chip 24 that is continuous between the LED regions 24-1 to 24-4. For example, the continuous portion may include portions of a growth substrate and/or lower portions of epitaxial structures that are adjacent the growth substrate. A number of electrical traces 50 may be arranged on the submount 48. In certain embodiments, the electrical traces 50 may form separate anode and cathode contacts for each of the LED regions 24-1 to 24-4 so that the LED regions 24-1 to 24-4 may be individually addressable. In certain embodiments, the streets 86 may be filled with the light-altering material 54 to provide improved contrast and reduced optical cross-talk between the LED regions 24-1 to 24-4. In this regard, the LED package 84 may be well suited for pixelated-LED applications where each of the LED regions 24-1 to 24-4 may form an individual pixel. While the cover structure 16 is illustrated in a similar manner as described for FIG. 3, the cover structure of FIG. 17 may embody any of the previously described cover structures in any of FIGS. 3-16, depending on desired emission characteristics.

FIG. 18 is a cross-sectional view of an LED package 88 that is similar to the LED package 84 of FIG. 17 for embodiments where the streets 86 may be formed though an entire thickness of the LED chip 24. In this manner, each of the LED regions 24-1 to 24-4 may embody completely subdivided regions of the LED chip 24. In certain embodiments, this may provide further improved contrast and reduced optical cross-talk between the LED regions 24-1 to 24-4 by having the streets 86 extend entirely through the LED chip 24. In still further embodiments, the streets 86 may be entirely filled with the light-altering material 54 to provide additional improvements in contrast between the LED regions 24-1 to 24-4. In other embodiments, the streets 86 may form air gaps between the LED regions 24-1 to 24-4 that provide an index of refraction interface that may also improve optical contract and sharpness between individual ones of the LED regions 24-1 to 24-4. FIG. 18 may also embody configurations that include multiple LED chips that not monolithically formed. For example, each of the LED regions 24-1 to 24-4 may embody separately formed LED chips that are mounted in close proximity to one another on the submount 48 with the streets 86 defined between them. While the cover structure 16 is illustrated in a similar manner as described for FIG. 3, the cover structure of FIG. 18 may embody any of the previously described cover structures in any of FIGS. 3-16, depending on desired emission characteristics.

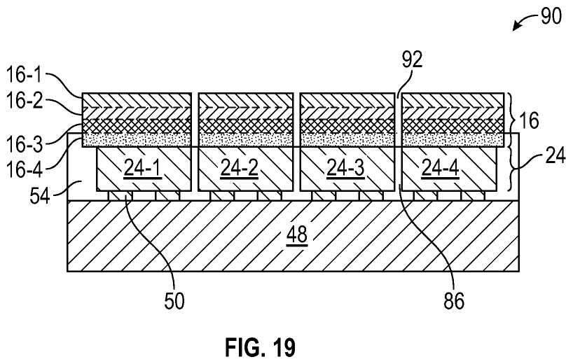

FIG. 19 is a cross-sectional view of an LED package 90 that is similar to the LED package 88 of FIG. 18 for embodiments where recesses and/or openings 92 are formed in the cover structure 16 that are registered with the streets 86. The openings 92 may be formed before or after the cover structure 16 is mounted to the LED package 90. In this regard, boundaries between each of the LED regions 24-1 to 24-4 as initially defined by the streets 86 may extend either partially or entirely through the cover structure 16, thereby providing further improvements to optical contract and sharpness between individual ones of the LED regions 24-1 to 24-4. In certain embodiments, the openings 92 are arranged to extend entirely through the cover structure 16, while in other embodiments, the openings 92 may extend only partially through the cover structure 16. The openings 92 may form air gaps that provide an index of refraction interface within the cover structure 16 that may improve optical contract and sharpness between individual ones of the underlying LED regions 24-1 to 24-4. In other embodiments, the openings 92 and/or the corresponding streets 86 may be filled with a light-altering material after the cover structure 16 and openings 92 are provided in the LED package 90. Cover structures according to any of the previously described embodiments may further include various shapes that are configured to improve light extraction and/or alter emission patterns for corresponding LED packages. Various shapes include beveled edges or sidewalls and/or various nonplanar emission surfaces of the cover structure. In still further embodiments, cover structures may include various shapes that correspond with other LED package elements. For example, cover structures may include recesses and/or light blocking regions that correspond with other LED package elements that may be light-absorbing, including electrical overstress devices such as ESD chips and/or Zener diodes.

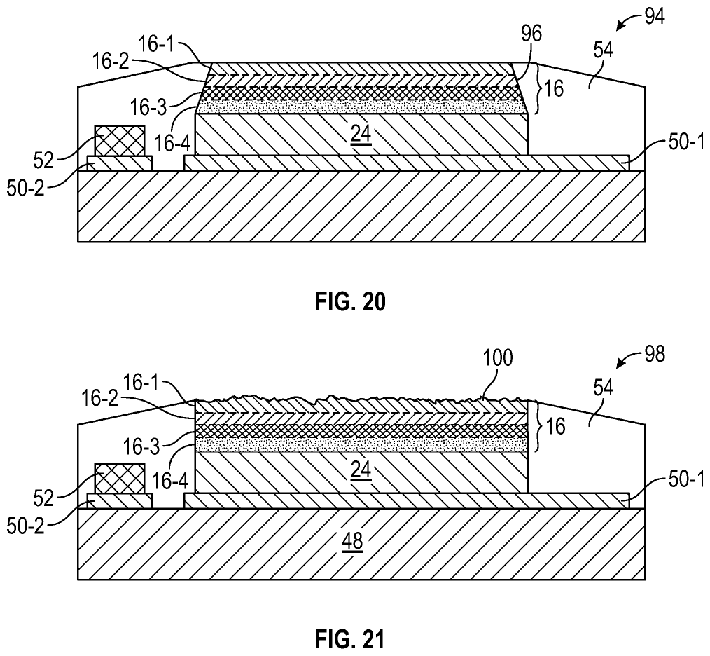

FIG. 20 is a cross-sectional view of an LED package 94 that is similar to the LED package 46 of FIG. 3 and where the cover structure 16 is formed with one or more beveled edges 96. The beveled edges 96 may form non-perpendicular sidewalls of the cover structure 16. In certain embodiments, the beveled edges 96 may be formed by applying a saw blade with an angled cutting edge to singulate the cover structure 16. The beveled edges 96 may provide angled surfaces that redirect light emissions toward a desired emission direction. In certain embodiments, the light-altering material 54 may cover the beveled edges 96. In other embodiments, the light-altering material 54 may only partially cover the beveled edges 96, thereby providing at least a portion of the beveled edges that extend above the light-altering material to provide light extraction surfaces. As illustrated in FIG. 20, the beveled edges 96 may taper the cover structure 16 from a wider width near the LED chip 24 to a narrower width near an exterior of the LED package 94. If a different emission pattern is desired, the taper may be reversed such that the beveled edges 96 taper the cover structure 16 from a narrower width near the LED chip 24 to a wider width near an exterior of the LED package 94.

FIG. 21 is a cross-sectional view of an LED package 98 that is similar to the LED package 46 of FIG. 3 and where the cover structure 16 is formed with a textured surface 100 for light extraction. As illustrated, the textured surface 100 may be arranged as a topmost surface of the cover structure 16. The textured surface 100 may be formed by an etching process, such as reactive ion etching, that provides the textured surface 100 as a randomized and nonplanar surface the reduces internal reflections of light from the LED chip 24.

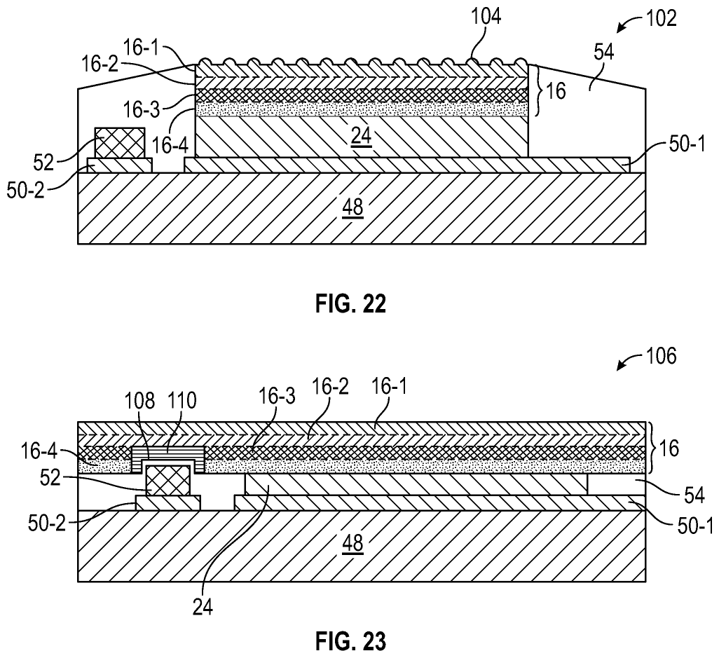

FIG. 22 is a cross-sectional view of an LED package 102 that is similar to the LED package 46 of FIG. 3 and where the cover structure 16 is formed with a patterned surface 104 for light extraction. The patterned surface 104 may serve a similar purpose as the textured surface 100 of FIG. 21 by reducing instances of internal reflection of light from the LED chip 24. The patterned surface 104 may be formed by an etching process through a patterned mask or micro-mask, a molding process, and/or a pressing or stamping process.

FIG. 23 is a cross-sectional view of an LED package 106 that is similar to the LED package 46 of FIG. 3 and where the cover structure 16 is formed with a shape that corresponds with a non-light-emitting element of the LED package 106. In certain embodiments, the cover structure 16 may be sized to also cover other non-light-emitting elements of the LED package 106, such as the electrical overstress device 52. This may reduce the appearance of the electrical overstress device 52 from outside of the LED package 106. In certain embodiments, the electrical overstress device 52 may have a height or thickness that extends above the LED chip 24. For example, a growth substrate of the LED chip 24 may be removed after mounting the LED chip 24 to the submount 48. Accordingly, an attachment surface of the cover structure 16 on the LED chip 24 may be closer to the submount 48 than a top surface of the electrical overstress device 52. In this regard, the cover structure 16 may be formed with a recess 108 that corresponds with the electrical overstress device 52 so that the cover structure 16 may be attached to the LED chip 24 along a horizontal plane that is below the top surface of the electrical overstress device 52. In certain embodiments, the cover structure 16 may also include a light-altering region 110 that is registered with the electrical overstress device 52. The light-altering region 110 may extend through one or more of the sublayers 16-1 to 16-4. In certain embodiments, the light-altering region 110 may comprise light-reflecting materials that redirect light from the LED chip 24 and/or the cover structure 16 away from the electrical overstress device 52. In further embodiments, multiple ones of the LED chip 24 may be provided on the submount 48 on opposing sides of the electrical overstress device 52, and the cover structure 16 may accordingly be shaped to accommodate any mismatched heights of underlying LED chips and the electrical overstress device 52. As illustrated, the cover structure 16 may include a lateral width that corresponds to a lateral width of the submount 48. In certain embodiments, singulation of the cover structure 16 from a larger sheet may be performed after attachment to the submount 48. Accordingly, the cover structure 16 and the submount 48 may be singulated together from larger panels in a single separation step. In certain embodiments, the light-altering material 54 may be provided between the cover structure 16 and portions of the submount 48 that are outside a mounting area of the LED chip 24 and the electrical overstress device 52. In such embodiments, one or more sidewalls of the LED package 106 after single-step singulation may include sidewalls of the cover structure 16, the light-altering material 54 and the submount 48.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) package comprising:
a submount;
at least one LED chip on the submount; and
a cover structure on the at least on LED chip, wherein the cover structure comprises:
a first sublayer comprising a first arrangement of a first optical material; and
a second sublayer comprising a second arrangement of a second optical material, wherein the first arrangement is different than the second arrangement.

2. The LED package of claim 1, wherein the cover structure comprises a host material of at least one of a glass and a ceramic.

3. The LED package of claim 2, wherein the first optical material and the second optical material comprise one or more of a lumiphoric material, a material with a different index of refraction than the host material, a light-scattering material, and a light-diffusing material.

4. The LED package of claim 1, wherein:
the first sublayer is arranged between the at least one LED chip and the second sublayer; and
the first optical material and the second optical material comprise a same lumiphoric material, wherein the first arrangement of the first sublayer comprises a higher quantity of the lumiphoric material than the second arrangement of the second sublayer.

5. The LED package of claim 4, wherein the cover structure further comprises a third sublayer and a fourth sublayer that each comprise the lumiphoric material, and the lumiphoric material is arranged in decreasing quantities in the cover structure in a direction away from the at least one LED chip.

6. The LED package of claim 1, wherein:
the first sublayer is arranged between the at least one LED chip and the second sublayer;
the first optical material comprises a first lumiphoric material;
the second optical material comprise a second lumiphoric material that is different than the first lumiphoric material.

7. The LED package of claim 6, wherein the first lumiphoric material is configured to provide a longer peak wavelength than the second lumiphoric material.

8. The LED package of claim 6, further comprising at least one additional sublayer that is devoid of lumiphoric materials.

9. The LED package of claim 8, wherein the at least one additional sublayer comprises light-scattering particles.

10. The LED package of claim 1, wherein the second optical material is arranged in a first subregion of the second sublayer.

11. The LED package of claim 10, wherein a lateral width of the first subregion of the second sublayer is less than a lateral width of the cover structure.

12. The LED package of claim 10, wherein the first subregion of the second sublayer is laterally surrounded by a second subregion of the second sublayer.

13. The LED package of claim 12, wherein the second subregion comprises light-scattering materials and is devoid of lumiphoric materials.

14. The LED package of claim 12, wherein the second subregion of the second sublayer comprises the first optical material.

15. The LED package of claim 1, wherein the at least one LED chip is a monolithic LED chip that comprises a plurality of individual LED regions of the monolithic LED chip.

16. The LED package of claim 15, wherein a plurality of streets are defined at least partially through the monolithic LED chip and define the plurality of individual LED regions.

17. The LED package of claim 16, wherein the plurality of streets are at least partially filled with a light-altering material.

18. The LED package of claim 16, wherein the cover structure forms a plurality of openings that are registered with the plurality of streets.

19. The LED package of claim 1, wherein the cover structure comprises a beveled edge.

20. The LED package of claim 1, wherein a surface of the cover structure comprises a nonplanar emission surface.

21. The LED package of claim 1, further comprising a non-light-emitting element on the submount that has a greater height than a height of the at least one LED chip, wherein the cover structure forms a recess that is registered with the non-light-emitting element.

22. A light emitting diode (LED) package comprising:
a submount;
at least one LED chip on the submount; and
a cover structure on the at least on LED chip, wherein the cover structure comprises:
a first sublayer within the cover structure, wherein the first sublayer comprises a first lumiphoric material; and
a second sublayer within the cover structure, wherein the second sublayer comprises a second lumiphoric material that is different than the first lumiphoric material.

23. The LED package of claim 22, further comprising at least one additional sublayer that is devoid of lumiphoric materials.

24. The LED package of claim 23, wherein the at least one additional sublayer comprises light-scattering particles.

25. The LED package of claim 22, wherein the second lumiphoric material is arranged in a first subregion of the second sublayer.

26. The LED package of claim 25, wherein a lateral width of the first subregion of the second sublayer is less than a lateral width of the cover structure.

27. The LED package of claim 25, wherein the first subregion of the second sublayer is laterally surrounded by a second subregion of the second sublayer.

28. The LED package of claim 27, wherein the second subregion comprises light-scattering materials and is devoid of lumiphoric materials.

29. The LED package of claim 27, wherein the second subregion of the second sublayer comprises the first lumiphoric material.

30. The LED package of claim 22, wherein the at least one LED chip is a monolithic LED chip that comprises a plurality of individual LED regions of the monolithic LED chip.

31. The LED package of claim 30, wherein a plurality of streets are defined at least partially through the monolithic LED chip and define the plurality of individual LED regions.

32. The LED package of claim 31, wherein the plurality of streets are at least partially filled with a light-altering material.

33. A method comprising:
providing a first sheet comprising a precursor material and a first arrangement of a first optical material;
providing a second sheet comprising the precursor material and a second arrangement of a second optical material that is different than the first arrangement of the first optical material;
pressing and firing the first sheet together with the second sheet to form a cover structure that comprises the first arrangement and the second arrangement embedded within the cover structure; and
attaching the cover structure over a light emitting diode (LED) chip.

34. The method of claim 33, wherein the precursor material comprises at least one of glass frit and ceramic materials that forms a host material for the cover structure after pressing and firing.

35. The method of claim 34, wherein the first optical material and the second optical material comprise one or more of a lumiphoric material, a material with a different index of refraction than the host material, a light-scattering material, and a light-diffusing material.

36. The method of claim 33, wherein the first optical material and the second optical material comprise a same lumiphoric material, and the first arrangement comprises a higher quantity of the lumiphoric material than the second arrangement.

37. The method of claim 33, wherein the first optical material and the second optical material comprise different lumiphoric materials.

38. The method of claim 33, further comprising reducing a thickness of the cover structure before attaching the cover structure over the LED chip.

39. The method of claim 33, wherein the first arrangement comprises a subregion of the first sheet that comprises the first optical material.

40. The method of claim 39, further comprising forming a well in the first sheet and filling the well with the first optical material to form the subregion before pressing and firing the first sheet together with the second sheet.

41. The method of claim 33, further comprising selectively removing one or more portions of the cover structure.

42. The method of claim 41, wherein the one or more portions of the cover structure are selectively removed after the cover structure is attached over the LED chip.
